(19) United States
(12) Patent Application Publication
(10) Pub. No.: US 2026/0026021 A1
(43) Pub. Date: Jan. 22, 2026

(54) CAPACITOR STRUCTURE AND FABRICATION METHOD THEREOF

(71) Applicant: UNITED MICROELECTRONICS CORP., Hsin-Chu City (TW)

(72) Inventors: Yen-Tsai Yi, Tainan City (TW); Wei-Chuan Tsai, Changhua County (TW); Hsiang-Wen Ke, Kaohsiung City (TW); Jin-Yan Chiou, Tainan City (TW)

(73) Assignee: UNITED MICROELECTRONICS CORP., Hsin-Chu City (TW)

(21) Appl. No.: 18/797,522

(22) Filed: Aug. 8, 2024

(30) Foreign Application Priority Data
Jul. 22, 2024 (TW) 113127273

(51) Int. Cl. H10D 1/68; H10D 1/00

(52) U.S. Cl. CPC H10D 1/696; H10D 1/042; H10D 1/716

(57) ABSTRACT

A capacitor structure includes a substrate; a bottom electrode layer disposed on the substrate; a capacitor dielectric layer disposed on the bottom electrode layer; a first top electrode layer disposed on the capacitor dielectric layer; a second top electrode layer disposed on the capacitor dielectric layer and spaced apart from the first top electrode layer, wherein a trench is formed between a first sidewall of the first top electrode layer and a second sidewall of the second top electrode layer; a protection layer covering the first sidewall of the first top electrode layer and the second sidewall of the second top electrode layer; and an etch stop layer conformally covering the first top electrode layer, the second top electrode layer, the protection layer, and the capacitor dielectric layer at the bottom of the trench.

### BACKGROUND OF THE INVENTION

### 1. Field of the Invention

The present invention relates to the field of semiconductor technology, and in particular to an improved capacitor structure and a manufacturing method thereof.

### 2. Description of the Prior Art

Multi-Mini Capacitor (MMC) is a type of capacitor that consists of multiple smaller, lower voltage capacitors connected in series and parallel to achieve a higher overall voltage. MMCs are commonly used in high-voltage applications such as power transmission, renewable energy systems, and industrial applications.

In order to avoid damage to the MMC insulation layer in existing MMC manufacturing, wet etching is used instead of dry etching to etch the aluminum metal layer in the upper electrode. However, wet etching can cause severe undercutting of the aluminum metal layer.

### SUMMARY OF THE INVENTION

It is one object of the present invention to provide an improved capacitor structure and a manufacturing method thereof to solve the deficiencies or shortcomings of the existing technology.

One aspect of the invention provides a capacitor structure including a substrate; a bottom electrode layer disposed on the substrate; a capacitor dielectric layer disposed on the bottom electrode layer; a first top electrode layer disposed on the capacitor dielectric layer; a second top electrode layer disposed on the capacitor dielectric layer and spaced apart from the first top electrode layer, wherein a trench is disposed between a first sidewall of the first top electrode layer and a second sidewall of the second top electrode layer; a protection layer covering the first sidewall of the first top electrode layer and the second sidewall of the second top electrode layer; and an etch stop layer conformally covering the first top electrode layer, second top electrode layer, the protection layer, and the capacitor dielectric layer at a bottom of the trench.

According to some embodiments, the etch stop layer is in direct contact with the capacitor dielectric layer at a bottom of the trench.

According to some embodiments, the protection layer is not in direct contact with the capacitor dielectric layer.

According to some embodiments, an undercut feature is disposed between the protection layer and the capacitor dielectric layer.

According to some embodiments, an undercut feature is filled with the etch stop layer.

According to some embodiments, the first top electrode layer and the second top electrode layer are composed of multiple metal layers.

According to some embodiments, the multiple metal layers comprise a first metal layer on the capacitor dielectric layer, a second metal layer on the first metal layer, and a third metal layer on the second metal layer, wherein the first metal layer and the third metal layer comprise Ti or TiN, and the second metal layer comprises Al.

According to some embodiments, the first metal layer comprises an extension portion protruding from a sidewall of the second metal layer.

According to some embodiments, the protection layer comprises silicon oxide.

According to some embodiments, the etch stop layer comprises silicon nitride.

Another aspect of the invention provides a method for forming a capacitor structure. A substrate is provided. A bottom electrode layer is formed on the substrate. A capacitor dielectric layer is formed on the bottom electrode layer. A first top electrode layer is formed on the capacitor dielectric layer. A second top electrode layer is formed on the capacitor dielectric layer and spaced apart from the first top electrode layer. A trench is disposed between a first sidewall of the first top electrode layer and a second sidewall of the second top electrode layer. A protection layer is formed to cover the first sidewall of the first top electrode layer and the second sidewall of the second top electrode layer. An etch stop layer is formed to conformally cover the first top electrode layer, second top electrode layer, the protection layer, and the capacitor dielectric layer at a bottom of the trench.

According to some embodiments, the etch stop layer is in direct contact with the capacitor dielectric layer at a bottom of the trench.

According to some embodiments, the protection layer is not in direct contact with the capacitor dielectric layer.

According to some embodiments, an undercut feature is disposed between the protection layer and the capacitor dielectric layer.

According to some embodiments, an undercut feature is filled with the etch stop layer.

According to some embodiments, the first top electrode layer and the second top electrode layer are composed of multiple metal layers.

According to some embodiments, the multiple metal layers comprise a first metal layer on the capacitor dielectric layer, a second metal layer on the first metal layer, and a third metal layer on the second metal layer, wherein the first metal layer and the third metal layer comprise Ti or TiN, and the second metal layer comprises Al.

According to some embodiments, the first metal layer comprises an extension portion protruding from a sidewall of the second metal layer.

According to some embodiments, the protection layer comprises silicon oxide.

According to some embodiments, the etch stop layer comprises silicon nitride.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 are schematic cross-sectional diagrams showing a method of forming a capacitor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

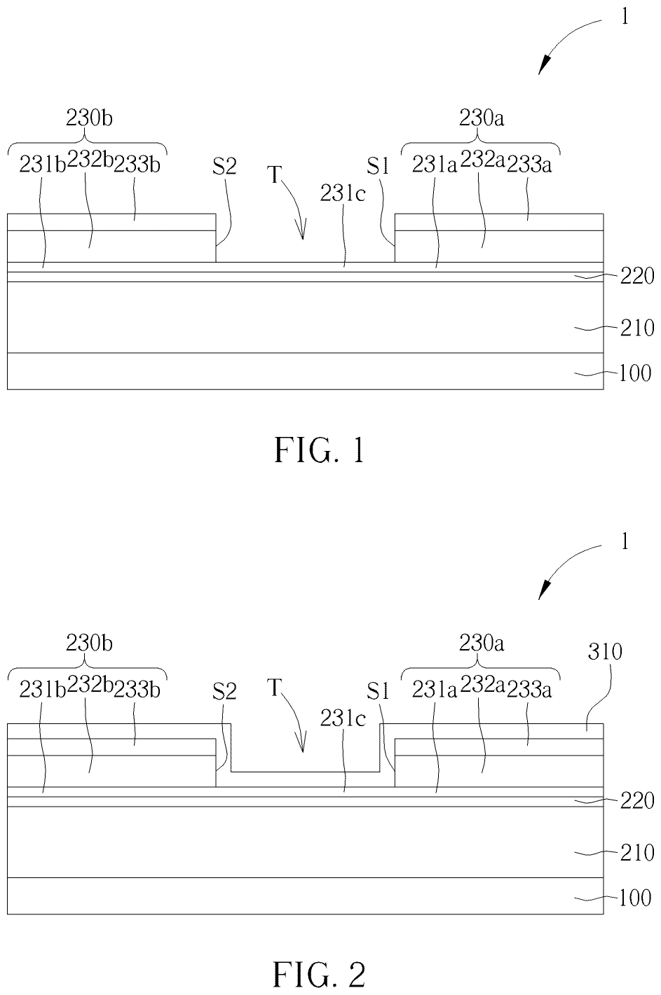

Please refer to FIG. 1 to FIG. 6, which are schematic cross-sectional diagrams showing an exemplary method of forming a capacitor structure 1 according to an embodiment of the present invention. As shown in FIG. 1, first, a substrate 100 is provided. For example, the substrate 100 may be a silicon substrate. The substrate 100 may include a dielectric layer, a metal layer or a circuit element, etc., which are not shown in the figures for the sake of simplicity. A bottom electrode layer 210 is formed on the substrate 100. According to an embodiment of the present invention, for example, the bottom electrode layer 210 may include Ti, TiN, Al or a combination thereof. A capacitor dielectric layer 220 is then formed on the bottom electrode layer 210. According to an embodiment of the present invention, for example, the capacitor dielectric layer 220 may include silicon nitride, but is not limited thereto.

Subsequently, a top electrode layer 230a and a top electrode layer 230b are formed on the capacitor dielectric layer 220. A trench T is provided between the sidewall S1 of the top electrode layer 230a and the sidewall S2 of the top electrode layer 230b. According to an embodiment of the present invention, for example, the trench T may be formed using a photolithography process and an etching process. According to an embodiment of the present invention, the top electrode layer 230a and the top electrode layer 230a are composed of multiple metal layers.

According to an embodiment of the present invention, for example, the top electrode layer 230a includes a metal layer 231a located on the capacitor dielectric layer 220, a metal layer 232a located on the metal layer 231a, and a metal layer 233a located on the metal layer 232a. The metal layer 231a and the metal layer 233a may comprise Ti, TiN, or a combination thereof, and the metal layer 232a may comprise Al. According to an embodiment of the present invention, for example, the thickness of the metal layer 231a is greater than the thickness of the metal layer 233a. At this point, the sidewall of the metal layer 231a is flush with the sidewall of the metal layer 232a, and together they form the sidewall S1.

According to an embodiment of the present invention, for example, the top electrode layer 230b includes a metal layer 231b located on the capacitor dielectric layer 220, a metal layer 232b located on the metal layer 231b, and a metal layer 233b located on the metal layer 232b. At this point, the metal layer 231a and the metal layer 231b are connected via the metal layer 231c. The metal layer 231b and the metal layer 233b may comprise Ti, TiN, or a combination thereof, and the metal layer 232b may comprise Al. According to an embodiment of the present invention, for example, the thickness of the metal layer 231b is greater than the thickness of the metal layer 233b. The sidewall of the metal layer 231b is flush with the sidewall of the metal layer 232b, and together they form the sidewall S2.

As shown in FIG. 2, a chemical vapor deposition (CVD) process or an atomic layer deposition (ALD) process is then performed to deposit a protection layer 310 on the substrate 100 in a blanket manner. The protection layer 310 covers the top surface and sidewall S1 of the top electrode layer 230a and the top surface and sidewall S2 of the top electrode layer 230b. At this point, the protection layer 310 also covers the metal layer 231c. According to an embodiment of the present invention, the protection layer 310 is not in direct contact with the capacitor dielectric layer 220. According to an embodiment of the present invention, for example, the protection layer 310 may include silicon oxide, but is not limited thereto.

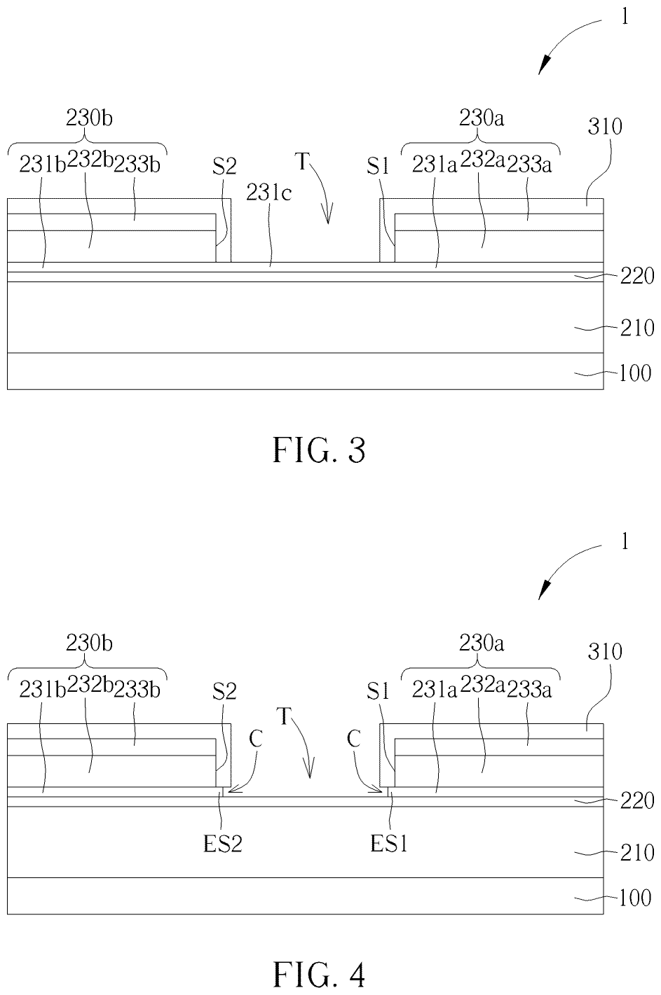

As shown in FIG. 3, the protection layer 310 directly above the metal layer 231c is then removed using a photolithography process and an etching process to expose the metal layer 231c in the trench T. At this point, the top surface and the sidewall S1 of the top electrode layer 230a and the top surface and the sidewall S2 of the top electrode layer 230b are still covered by the protection layer 310.

As shown in FIG. 4, a wet etching process is then performed to etch away the metal layer 231c that is not covered by the protection layer 310 through the trench T, disconnect the top electrode layer 230a and the top electrode layer 230b, and expose part of the capacitor dielectric layer 220. The above wet etching process may form an undercut feature C between the protection layer 310 and the capacitor dielectric layer 220. According to an embodiment of the present invention, the metal layer 231a of the top electrode layer 230a includes an extension portion ES1 protruding from the sidewall of the metal layer 232a. According to an embodiment of the present invention, the metal layer 231b of the top electrode layer 230b includes an extension portion ES2 protruding from the sidewall of the metal layer 232b.

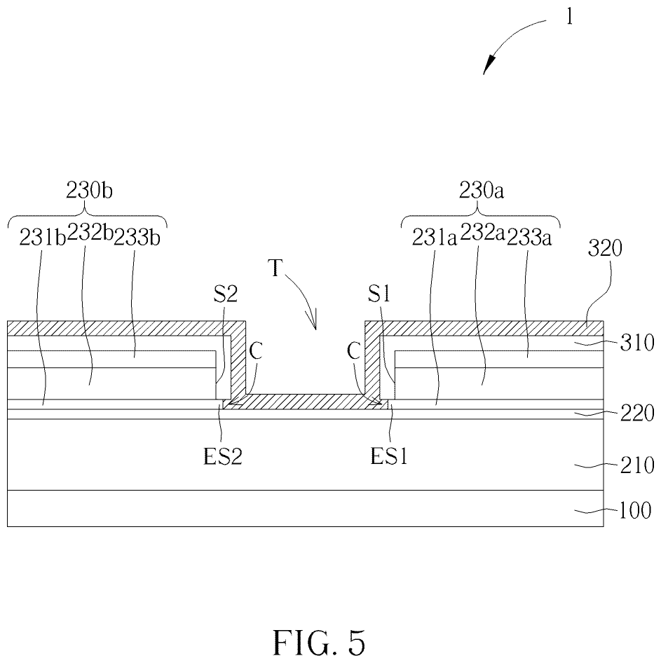

As shown in FIG. 5, a chemical vapor deposition (CVD) process or an atomic layer deposition (ALD) process is then performed to deposit an etch stop layer 320 on the substrate 100 in a blanket manner to conformally cover the top electrode layer 230a, the top electrode layer 230b, the protection layer 310, and the capacitor dielectric layer 220 at the bottom of trench T. According to an embodiment of the present invention, for example, the etch stop layer 320 may include silicon nitride, but is not limited thereto. According to an embodiment of the present invention, the etch stop layer 320 is in direct contact with the capacitor dielectric layer 220 at the bottom of the trench T.

According to an embodiment of the present invention, the etch stop layer 320 may be filled into the undercut feature C. According to some embodiments of the present invention, the etch stop layer 320 may completely fill the undercut feature C. According to some embodiments of the invention, etch stop layer 320 may not completely fill undercut feature C.

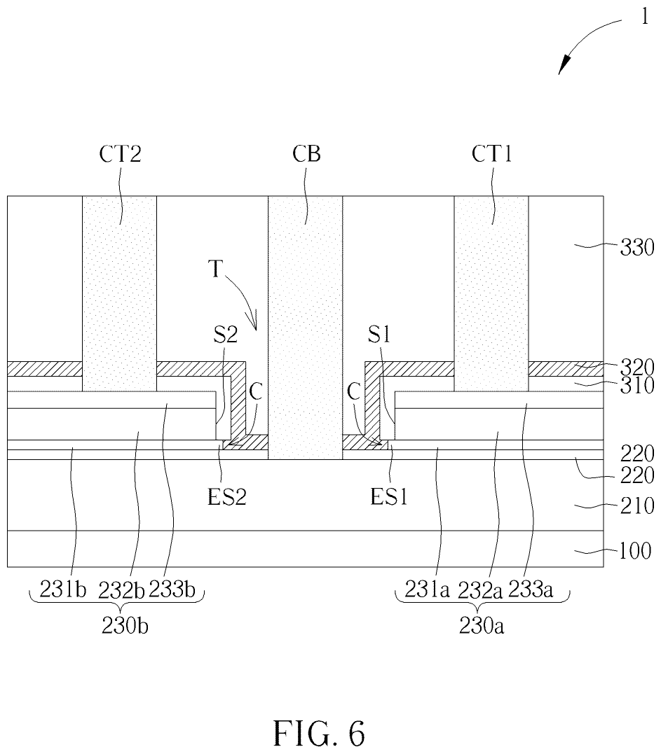

As shown in FIG. 6, a dielectric layer 330, such as a silicon oxide layer, a low dielectric constant material layer or an ultra-low dielectric constant material layer, is then deposited on the substrate 100 in a blanket manner, so that the dielectric layer 330 fills the trench T and covers the etch stop layer 320. A metallization process is then performed to form contact plugs CT1, CT2 and CB in the dielectric layer 330 to complete the capacitor structure 1. According to an embodiment of the present invention, the contact plug CT1 is electrically connected to the top electrode layer 230a and the contact plug CT2 is electrically connected to the top electrode layer 230b. The contact plug CB penetrates the dielectric layer 330, the etch stop layer 320 and the capacitor dielectric layer 220, and is electrically connected to the bottom electrode layer 210.

Structurally, as shown in FIG. 6, the capacitor structure 1 of the present invention includes a substrate 100; a bottom electrode layer 210 disposed on the substrate 100; a capacitor dielectric layer 220 disposed on the bottom electrode layer 210; a top electrode layer 230a disposed on the capacitor dielectric layer 220; and a top electrode layer 230b disposed on the capacitor dielectric layer 220 and spaced apart from the top electrode layer 230a. A trench T is provided between the sidewall S1 of the top electrode layer 230a and the sidewall S2 of the top electrode layer 230b. A protection layer 310 covers the sidewall S1 of the top electrode layer 230a and the sidewall S2 of the top electrode layer 230b. An etch stop layer 320 conformally covers the top electrode layer 230a and the top electrode layer 230b, the protection layer 310, and the capacitor dielectric layer 220 at the bottom of the trench T.

According to an embodiment of the present invention, the protection layer 310 includes silicon oxide, for example. According to an embodiment of the present invention, the etch stop layer 320 includes silicon nitride, for example.

According to an embodiment of the present invention, the etch stop layer 320 is in direct contact with the capacitor dielectric layer 220 at the bottom of the trench T. According to an embodiment of the present invention, the protection layer 310 is not in direct contact with the capacitor dielectric layer 220. According to an embodiment of the present invention, an undercut feature C is provided between the protection layer 310 and the capacitor dielectric layer 220. According to an embodiment of the present invention, the etch stop layer 320 fills into the undercut feature C.

According to an embodiment of the present invention, the top electrode layer 230a and the top electrode layer 230b are composed of multiple metal layers, including metal layers 231a and 231b located on the capacitor dielectric layer 220, and metal layers 232a and 232b respectively located on the metal layers 231a and 231b, and metal layers 233a and 233b respectively located on the metal layers 232a and 232b. The metal layers 231a and 231b and the metal layers 233a and 233b include, for example, Ti or TiN, and the metal layers 232a and 232b include, for example, Al.

According to an embodiment of the present invention, the metal layers 231a and 231b respectively include extension portions ES1 and ES2 protruding from the sidewalls of the metal layers 232a and 232b.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor structure, comprising:
a substrate;
a bottom electrode layer disposed on the substrate;
a capacitor dielectric layer disposed on the bottom electrode layer;
a first top electrode layer disposed on the capacitor dielectric layer;
a second top electrode layer disposed on the capacitor dielectric layer and spaced apart from the first top electrode layer, wherein a trench is disposed between a first sidewall of the first top electrode layer and a second sidewall of the second top electrode layer;
a protection layer covering the first sidewall of the first top electrode layer and the second sidewall of the second top electrode layer; and
an etch stop layer conformally covering the first top electrode layer, second top electrode layer, the protection layer, and the capacitor dielectric layer at a bottom of the trench.

2. The capacitor structure according to claim 1, wherein the etch stop layer is in direct contact with the capacitor dielectric layer at a bottom of the trench.

3. The capacitor structure according to claim 1, wherein the protection layer is not in direct contact with the capacitor dielectric layer.

4. The capacitor structure according to claim 1, wherein an undercut feature is disposed between the protection layer and the capacitor dielectric layer.

5. The capacitor structure according to claim 4, wherein an undercut feature is filled with the etch stop layer.

6. The capacitor structure according to claim 1, wherein the first top electrode layer and the second top electrode layer are composed of multiple metal layers.

7. The capacitor structure according to claim 1, wherein the multiple metal layers comprise a first metal layer on the capacitor dielectric layer, a second metal layer on the first metal layer, and a third metal layer on the second metal layer, wherein the first metal layer and the third metal layer comprise Ti or TiN, and the second metal layer comprises Al.

8. The capacitor structure according to claim 7, wherein the first metal layer comprises an extension portion protruding from a sidewall of the second metal layer.

9. The capacitor structure according to claim 1, wherein the protection layer comprises silicon oxide.

10. The capacitor structure according to claim 1, wherein the etch stop layer comprises silicon nitride.

11. A method for forming a capacitor structure, comprising:
providing a substrate;
forming a bottom electrode layer on the substrate;
forming a capacitor dielectric layer on the bottom electrode layer;
forming a first top electrode layer on the capacitor dielectric layer;
forming a second top electrode layer on the capacitor dielectric layer and spaced apart from the first top electrode layer, wherein a trench is disposed between a first sidewall of the first top electrode layer and a second sidewall of the second top electrode layer;
forming a protection layer covering the first sidewall of the first top electrode layer and the second sidewall of the second top electrode layer; and
forming an etch stop layer conformally covering the first top electrode layer, second top electrode layer, the protection layer, and the capacitor dielectric layer at a bottom of the trench.

12. The method according to claim 11, wherein the etch stop layer is in direct contact with the capacitor dielectric layer at a bottom of the trench.

13. The method according to claim 11, wherein the protection layer is not in direct contact with the capacitor dielectric layer.

14. The method according to claim 11, wherein an undercut feature is disposed between the protection layer and the capacitor dielectric layer.

15. The method according to claim 14, wherein an undercut feature is filled with the etch stop layer.

16. The method according to claim 11, wherein the first top electrode layer and the second top electrode layer are composed of multiple metal layers.

17. The method according to claim 11, wherein the multiple metal layers comprise a first metal layer on the capacitor dielectric layer, a second metal layer on the first metal layer, and a third metal layer on the second metal layer, wherein the first metal layer and the third metal layer comprise Ti or TiN, and the second metal layer comprises Al.

18. The method according to claim 17, wherein the first metal layer comprises an extension portion protruding from a sidewall of the second metal layer.

19. The method according to claim 11, wherein the protection layer comprises silicon oxide.

20. The method according to claim 11, wherein the etch stop layer comprises silicon nitride.
